(19) United States
(12) Patent Application Publication
(10) Pub. No.: US 2009/0102506 A1
(43) Pub. Date: Apr. 23, 2009

(54) ADAPTER

(75) Inventors: WEI-DER TANG, Tu-Cheng (TW); CHIEH-HSUAN LEE, Tu-Cheng (TW); YAW-SHEN LAI, Tu-Cheng (TW); HAN-CHIEH CHANG, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/954,237

(22) Filed: Dec. 12, 2007

(30) Foreign Application Priority Data
Oct. 22, 2007 (CN) 200710202201.X

(51) Int. Cl. H03K 19/003

(52) U.S. Cl. 326/9

(57) ABSTRACT

An exemplary adapter comprises an input port for connecting to a first hardware device; an output port for connecting to a second hardware device; a standby output port for connecting to the second hardware device; a programmable logic device (PLD) having at least one input terminal connected to the input port, at least one output terminal connected to the output port, at least one standby output terminal connected to the standby output port, and at least one control terminal to receive a voltage signal; and a jumper connected to the control terminal of the PLD to send a voltage signal thereto, wherein the input terminal of the PLD is selectively coupled to the output terminal or the standby output terminal of the PLD under the control of the voltage signal.

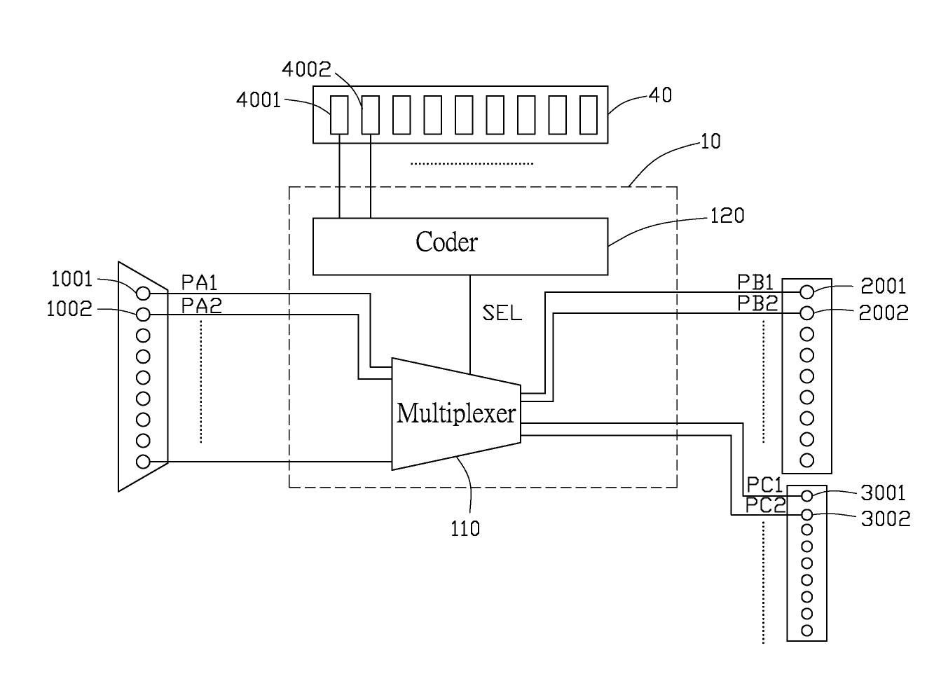

### CROSS-REFERENCES TO RELATED APPLICATION

Relevant subject matter is disclosed in a co-pending U.S. patent application (Attorney Docket No. US17087) filed on the same date and entitled “PATCH PANEL”, which is assigned to the same assignee as this patent application.

### BACKGROUND

1. Field of the Invention

The present invention relates to an adapter.

2. Description of Related Art

Conventionally, operators use an adapter or a patch panel to couple an electric device with another electric device for signal transmission. If one of the input or output terminals (which are arranged to connect to the devices) of the adapter becomes inoperable, the signal transmission will be stopped.

What is needed is an adapter with standby terminals to maintain signal transmission when one or more of the terminals connected to the devices become inoperable.

### SUMMARY

An exemplary adapter comprises an input port for connecting to a first hardware device; an output port for connecting to a second hardware device; a standby output port for connecting to the second hardware device; a programmable logic device (PLD) having at least one input terminal connected to the input port, at least one output terminal connected to the output port, at least one standby output terminal connected to the standby output port, and at least one control terminal to receive a voltage signal; and a jumper connected to the control terminal of the PLD to send a voltage signal thereto, wherein the input terminal of the PLD is selectively coupled to the output terminal or the standby output terminal of the PLD under the control of the voltage signal.

Other advantages and novel features of the present invention will become more apparent from the following detailed description of preferred embodiment when taken in conjunction with the accompanying drawing, in which:

### BRIEF DESCRIPTION OF THE DRAWINGS

The drawing is a circuit diagram of an adapter in accordance with an embodiment of the present invention.

### DETAILED DESCRIPTION

Referring to the drawing, an adapter in accordance with an embodiment of the present invention includes an input port having two terminals 1001 and 1002, an output port having two terminals 2001 and 2002, a standby output port having two terminals 3001 and 3002, a programmable logic device (PLD) 10, and a jumper 40 with two terminals 4001 and 4002.

The input port is arranged to connect to a first hardware device, the output port is arranged to connect to a second hardware device, and the standby output port is arranged to connect to the second hardware device.

The PLD 10 includes a multiplexer 110 and a coder 120. The multiplexer 110 includes two input terminals PA1 and PA2, four output terminals PB1, PB2, PC1, and PC2, and a control terminal SEL. The input terminals PA1 and PA2 of the multiplexer 110 are connected to the terminals 1001 and 1002 of the input port respectively. The output terminals PB1 and PB2 of the multiplexer 110 are connected to the terminals 2001 and 2002 of the output port respectively. The output terminals PC1 and PC2 of the multiplexer 110 are connected to terminals the 3001 and 3002 of the standby output port respectively. The control terminal SEL is connected to the coder 120. The coder 120 is connected to the jumper 40. The jumper 40 defines two terminals 4001 and 4002 connected to the coder 120 to send a first voltage signal and a second voltage signal. The coder 120 receives the voltage signals and translates the voltage signals into control signals.

In this embodiment of the invention, when the terminal 4001 of the jumper 40 is at a high level, the coder 120 sends a first control signal to the multiplexer 110 to couple the input terminal PA1 to the output terminal PB1. When the terminal 4001 of the jumper 40 is at a low level, the coder 120 sends a second control signal to the multiplexer 110 to couple the input terminal PA1 to the output terminal PC1. When the terminal 4002 of the jumper 40 is at a high level, the coder 120 sends a third control signal to the multiplexer 110 to couple the input terminal PA2 to the output terminal PB2. When the terminal 4002 of the jumper 40 is at a low level, the coder 120 sends a fourth control signal to the multiplexer 110 to couple the input terminal PA2 to the output terminal PC2. Therefore, the terminal 1001 of the input port is selectively coupled to the terminal 2001 of the output port or the terminal 3001 of the standby output port under the control of the jumper 40.

In this embodiment of the invention, the amount of the terminals of the input port is two, the amount of the terminals of the output port, standby output port, and jumper is the same as the input port. The amount of the terminals of the input port, output port, or standby output port is not limited to two, it also can be just one, or more than two.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An adapter comprising:
an input port for connecting to a first hardware device;
an output port for connecting to a second hardware device;
a standby output port for connecting to the second hardware device;
a programmable logic device (PLD) having at least one input terminal connected to the input port, at least one output terminal connected to the output port, at least one standby output terminal connected to the standby output port, and at least one control terminal to receive a voltage signal; and
a jumper connected to the control terminal of the PLD to send a voltage signal thereto,
wherein the input terminal of the PLD is selectively coupled to the output terminal or the standby output terminal of the PLD under the control of the voltage signal.

2. The adapter as claimed in claim 1, wherein the input terminal of the PLD is coupled to the output terminal of the PLD when the voltage signal is at a low level, and is coupled to the standby output terminal when the voltage signal is at a high level.

3. An adapter comprising:
a jumper arranged to send a voltage signal; and
a programmable logic device (PLD) comprising:
a multiplexer having a input terminal, a first output terminal, a second output terminal, and a control terminal arranged to receive a control signal, the input terminal of the multiplexer is selectively coupled to the first output terminal or the second output terminal under the controlled of the control signal; and
a coder connected between the jumper and the control terminal of the multiplexer to receive the voltage signal and send the control signal to the multiplexer according to the voltage signal.

4. The adapter as claimed in claim 3, wherein the input terminal of the multiplexer is coupled to the first output terminal of the multiplexer when the voltage signal is at a low level, and is coupled to the second output terminal when the voltage signal is at a high level.
